(19) United States
(12) Patent Application Publication
(10) Pub. No.: US 2015/0284847 A1
(43) Pub. Date: Oct. 8, 2015

(54) Method of Forming an Epitaxial Layer and Apparatus for Processing a Substrate Used for the Method

(71) Applicant: Samsung Electronics Co., Ltd., Suwon-si (KR)

(72) Inventors: Tae-Ki Hong, Seoul (KR); Young-Min Park, Suwon-si (KR); Hyoung-Won Oh, Hwaseong-si (KR); Jin-Hyuk Choi, Suwon-si (KR); Sang-Chul Han, Suwon-si (KR)

(21) Appl. No.: 14/520,768

(22) Filed: Oct. 22, 2014

(30) Foreign Application Priority Data
Apr. 8, 2014 (KR) 10-2014-0041653

(51) Int. Cl. C23C 16/455; C23C 16/511; H01L 21/02

(52) U.S. Cl. CPC C23C 16/45519; H01L 21/0262; H01L 21/02524; C23C 16/45565; C23C 16/511

(57) ABSTRACT

In a method of forming an epitaxial layer, a first plasma may be generated from a first reaction gas in a first region. The first plasma may be applied to a second reaction gas provided to a second region isolated from the first region to generate a second plasma from the second reaction gas. A blocking gas may be injected into the second region toward an edge of the substrate to help prevent the first plasma and the second plasma from being horizontally diffused. The first plasma and the second plasma may be applied to the substrate to form the epitaxial layer. Thus, the epitaxial layer may be formed at a temperature relatively lower than a temperature in a heating process.

### CROSS-RELATED APPLICATION

This application claims priority under 35 USC §119 to Korean Patent Application No. 10-2014-0041653, filed on Apr. 8, 2014, the contents of which are herein incorporated by reference in their entirety.

### BACKGROUND

Generally, an epitaxial layer may be formed by providing a reaction gas such as a silicon source gas to a semiconductor substrate such as a silicon substrate to grow silicon from the silicon substrate. Further, a selective epitaxial layer may be formed by providing reaction gases such as a silicon source gas and an etching gas to a silicon substrate to grow silicon from the silicon substrate and to etch a portion of the silicon on an insulating layer of the silicon substrate using the etching gas.

According to related arts, the epitaxial layer may be formed by a process for heating the reaction gases. However, because the heating process may require a high temperature, the heating process may cause damage to the semiconductor substrate, reduce of a life span of a deposition apparatus, introduce difficulties with recipes in the deposition apparatus, etc.

### SUMMARY

Example embodiments relate to a method of forming an epitaxial layer and an apparatus for processing a substrate used for carrying out the method. More particularly, example embodiments relate to a method of forming an epitaxial layer using a selective epitaxial growth (SEG) process, and an apparatus for processing a substrate used for carrying out the method.

Example embodiments provide a method of forming an epitaxial layer at a low temperature.

Example embodiments also provide an apparatus for processing a substrate used for carrying out the above-mentioned method.

According to example embodiments, there may be provided a method of forming an epitaxial layer. In the method of forming the epitaxial layer, a first plasma may be generated from a first reaction gas in a first region of a chamber. The first plasma may be applied to a second reaction gas provided to a second region of the chamber that is isolated from the first region to generate a second plasma from the second reaction gas. A blocking gas may be injected into the second region toward an edge of the substrate to help prevent the first plasma and the second plasma from being horizontally diffused. The first plasma and the second plasma may be applied to the substrate to form the epitaxial layer.

In example embodiments, generating the first plasma may include applying a first microwave to the first reaction gas. Generating the second plasma may include applying a second microwave having an energy lower than an energy of the first microwave to the second reaction gas.

In example embodiments, the second region may be positioned between the substrate and the first region.

In example embodiments, the first reaction gas may include a hydrogen gas and an argon gas.

In example embodiments, the second reaction gas may include a silicon gas and a PH₃ gas.

In example embodiments, the blocking gas may include a hydrogen gas.

According to example embodiments, there may be provided an apparatus for processing a substrate. The apparatus may include a chamber, a showerhead, a first nozzle, a second nozzle and a plasma-generating unit. The chamber may be configured to receive the substrate. The showerhead may be configured to divide an inner space of the chamber into a first region and a second region. The showerhead may inject a second reaction gas to the substrate through the second region. The first nozzle may inject a first reaction gas to the first region. The plasma-generating unit may be configured to generate a first plasma from the first reaction gas in the first region, and a second plasma from the second reaction gas in the second region. The second nozzle may be arranged in the second region to inject a blocking gas for preventing or suppressing horizontal diffusions of the first plasma and the second plasma toward an edge of the substrate.

In example embodiments, the first region may be positioned between the showerhead and the plasma-generating unit. The second region may be positioned between the substrate and the showerhead.

In example embodiments, the showerhead may have a plurality of openings configured to inject the second reaction gas. A ratio of an area of the openings with respect to a surface area of the showerhead may be about 30% to about 70%.

In example embodiments, the showerhead may include a first block, a second block and a third block. The second block may be configured to make contact with a lower surface of the first block. The second block may have a first gas passageway into which a silicon gas in the second reaction gas may be introduced. The third block may be configured to make contact with a lower surface of the second block. The third block may have a second gas passageway into which a PH₃ gas in the second reaction gas may be introduced.

In example embodiments, the third block may have a first gas outlet in fluidic communication with the first gas passageway to inject the silicon gas, and a second gas outlet in fluidic communication with the second gas passageway to inject the PH₃ gas.

In example embodiments, the first gas outlet may be arranged at a central portion of the third block. The second gas outlet may be arranged at an edge portion of the third block.

In example embodiments, the plasma-generating unit may include a microwave-applying member configured to applying a microwave to the first reaction gas and the second reaction gas.

In example embodiments, the apparatus may further include a stage arranged on a bottom surface of the chamber to support the substrate.

In example embodiments, the apparatus may further include a heater arranged in the stage.

According to example embodiments, there may be provided an apparatus for processing a substrate. The apparatus may include: a chamber; a showerhead in the chamber, the showerhead dividing an inner space of the chamber into an upper region and a lower region; a stage configured to support the substrate in the lower region; a first nozzle configured to inject a first reaction gas into the upper region; at least one gas outlet in the showerhead configured to inject a second reaction gas into the lower region; and a plasma-generating unit configured to generate a first plasma from the first reaction gas in the upper region and a second plasma from the second reaction gas in the lower region.

In example embodiments, the apparatus may further include: first gas passageway in the showerhead through which a silicon gas in the second reaction gas is introduced to the showerhead; and a second gas passageway in the showerhead through which a PH₃ gas in the second reaction gas is introduced to the showerhead.

In example embodiments, the at least one gas outlet may include: a first gas outlet that is in fluid communication with the first gas passageway and is configured to inject the silicon gas into the lower region; and a second gas outlet that is in fluid communication with the second gas passageway and is configured to inject the PH₃ gas into the lower region.

In example embodiments, the first gas outlet may be positioned at a central portion of the showerhead, and the second gas outlet may be positioned at an edge portion of the showerhead.

In example embodiments, the apparatus may further include a second nozzle configured to inject a blocking gas into the lower region and to an edge portion of the substrate for suppressing horizontal diffusion of the first plasma and the second plasma.

According to example embodiments, the epitaxial layer may be formed using the plasma. Thus, the epitaxial layer may be formed at a temperature relatively lower than a temperature in a heating process. Further, the first plasma and the second plasma may be generated in the first region and the second region that may be isolated from each other, so that the plasma may have a desired density. As a result, the epitaxial layer formed using the plasma may have a desired shape. Particularly, the blocking gas may be injected toward the edge of the substrate so that the epitaxial layer may have improved thickness uniformity.

Further, the apparatus may individually generate the first plasma and the second plasma in the first region and the second region that may be isolated from each other by the showerhead so that the generations of the first plasma and the second plasma may be accurately controlled. Particularly, the generation of the second plasma may be assisted by introducing the first plasma into the second reaction gas so that recipes for generating the second plasma may be optimized.

### BRIEF DESCRIPTION OF THE DRAWINGS

Example embodiments will be more clearly understood from the following detailed description taken in conjunction with the accompanying drawings. FIGS. 1 to 11 represent non-limiting, example embodiments as described herein.

FIG. 1 is a cross-sectional view illustrating an apparatus for processing a substrate in accordance with example embodiments;

FIG. 2 is an enlarged perspective view illustrating a showerhead of the apparatus in FIG. 1;

FIG. 3 is an enlarged cross-sectional view illustrating the showerhead in FIG. 2;

FIG. 4 is a perspective view illustrating a showerhead in accordance with example embodiments;

FIGS. 5 and 6 are and plan views illustrating showerheads in accordance with example embodiments;

FIG. 7 is a graph showing a growth thickness of an epitaxial layer over time.

FIG. 8 is a graph showing a deposition rate of an epitaxial layer with respect to an open ratio of a showerhead;

FIG. 9 is a flow chart illustrating a method of forming an epitaxial layer using the apparatus in FIG. 1;

FIG. 10 is a cross-sectional view illustrating an apparatus for processing a substrate in accordance with example embodiments; and

FIG. 11 is a flow chart illustrating a method of forming an epitaxial layer using the apparatus in FIG. 10.

### DETAILED DESCRIPTION OF THE EMBODIMENTS

Various example embodiments will be described more fully hereinafter with reference to the accompanying drawings, in which some example embodiments are shown. The present inventive concepts may, however, be embodied in many different forms and should not be construed as limited to the example embodiments set forth herein. Rather, these example embodiments are provided so that this disclosure will be thorough and complete, and will fully convey the scope of the present inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

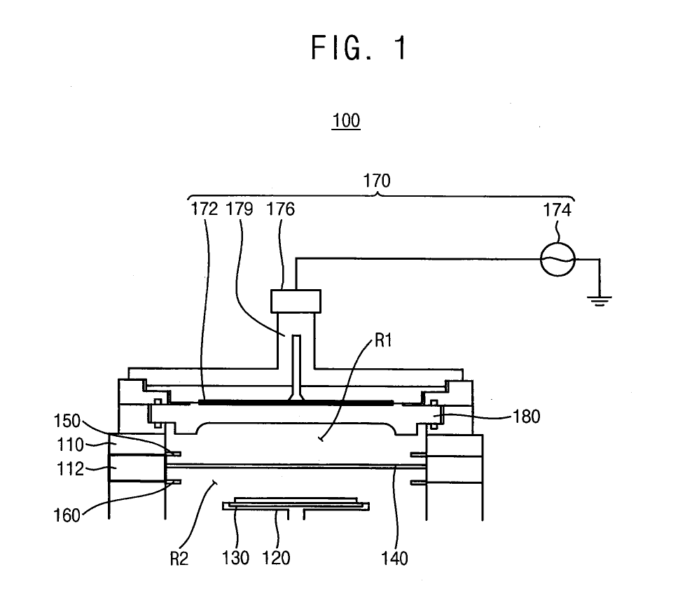

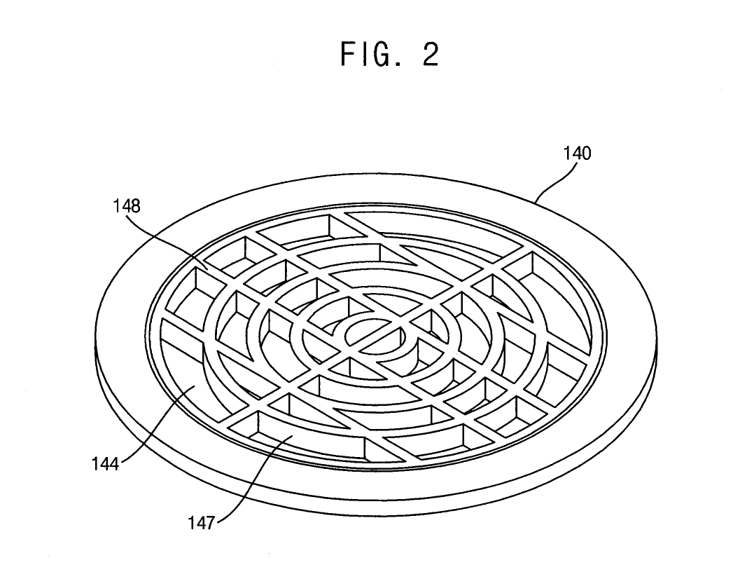

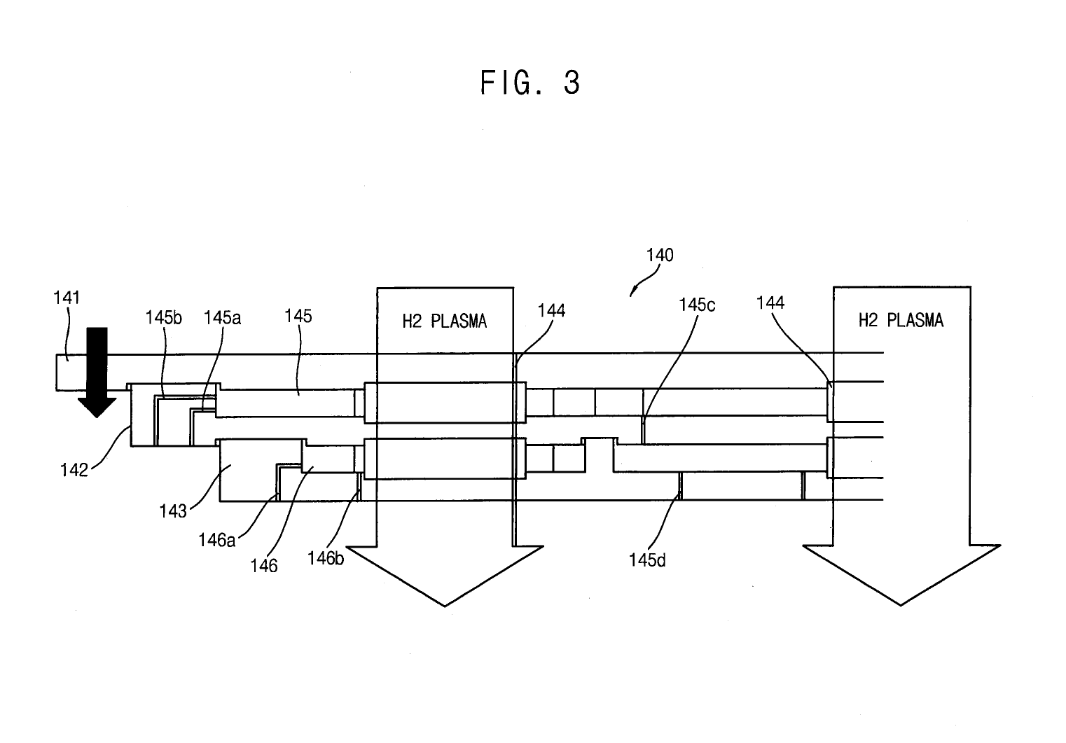

FIG. 1 is a cross-sectional view illustrating an apparatus for processing a substrate in accordance with example embodiments, FIG. 2 is an enlarged perspective view illustrating a showerhead of the apparatus in FIG. 1, and FIG. 3 is an enlarged cross-sectional view illustrating the showerhead in FIG. 2.

Referring to FIG. 1, an apparatus 100 for processing a substrate in accordance with this example embodiment may include a chamber 110, a stage 120, a heater 130, a showerhead 140, a first nozzle 150, a second nozzle 160 and a plasma-generating unit 170.

In example embodiments, the apparatus 100 may be configured to form a layer on the substrate using a plasma. The substrate may be or include a semiconductor substrate, a glass substrate, etc. For example, the apparatus 100 may be configured to form an epitaxial layer on the semiconductor substrate using a plasma generated from reaction gases.

The chamber 110 may be configured to receive the semiconductor substrate. Thus, the chamber 110 may have an inner space configured to receive the semiconductor substrate. In example embodiments, a height-adjusting block or member 112 may be arranged at a middle portion of the chamber 110 to adjust a height of the chamber 110. An insulating block 180 may be arranged at an upper surface or portion of the chamber 110.

The stage 120 may be arranged at or on a bottom surface or portion of the chamber 110. The semiconductor substrate may be placed on an upper surface of the stage 120. The heater 130 may be arranged in or on the stage 120 to provide the chamber 110 with a temperature for generating the plasma.

The showerhead 140 may be horizontally arranged on a middle portion of an inner surface of the chamber 110. Thus, the inner space of the chamber 110 may be divided into an upper space and a lower space by the showerhead 140. The lower space may be defined by the upper surface of the stage 120, a lower surface of the showerhead 140 and the inner surface of the chamber 110. The upper space may be defined by an upper surface of the showerhead 120, a lower surface of the insulating block 180 and the inner surface of the chamber 110. The upper space may correspond to a first or upper region R1. The lower space may correspond to a second or lower region R2.

A second reaction gas may be introduced into the showerhead 140. The second reaction gas may be injected into the second region R2 through openings of the showerhead 140. In example embodiments, the second reaction gas may include a gas including silicon. The second reaction gas may have a second dissociation energy. For example, the second reaction gas may include an SiH₄ gas, an SiH₂Cl₂ (DCS) gas, etc. Additionally, the second reaction gas may further include a PH₃ gas. The PH₃ gas may be used as a doping gas in the epitaxial layer. The second reaction gas may be converted into a second plasma in the second region R2 by the plasma-generating unit 170. The silicon in the second plasma may be applied to the semiconductor substrate to grow the epitaxial layer from the semiconductor substrate.

Additionally, a cooling gas may be introduced into the showerhead 140. The cooling gas may include a hydrogen gas.

Referring to FIG. 2, the showerhead 140 may include a plurality of circular portions 147 and a plurality of straight portions 148. The circular portions 147 may be concentrically arranged. The straight portions 148 may cross at least some of the circular portions 147. Any one of the straight portions 148 may pass a center point of the showerhead 140. In contrast, the rest of the straight portions 148, which may not pass the center point of the showerhead 140, may be arranged in parallel with each other. Further, the straight portion 148 passing the center point of the showerhead 140 may lie at a right angle relative to the rest of the straight portions 148. Thus, the showerhead 148 may have the openings 144 defined by the circular portions 147 and the straight portions 148. Because the plasma may be applied to the semiconductor substrate through the openings 144, an open ratio (%), which may mean a ratio of a total area of the openings 144 with respect to the a surface area of the showerhead 140, may be determined in accordance with kinds or types of the reaction gases. In example embodiments, the open ratio may be about 45%.

Referring to FIG. 3, the showerhead 140 may include a first block 141, a second block 142 and a third block 143. The second block 142 may make contact with a lower surface of the first block 141. The third block 143 may make contact with a lower surface of the second block 142. The openings 144 may be vertically formed through the first block 141, the second block 142 and the third block 143.

A first gas passageway 145 may be formed at an upper surface of the second block 142. Because the upper surface of the second block 142 may make contact with the lower surface of the first block 141, the first gas passageway 145 may be isolated from the outside. A first gas inlet 145a may be in fluid communication with the first gas passageway 145. The SiH₄ gas may be introduced into the first gas inlet 145a. A cooling gas inlet 145b may be in fluid communication with the first gas passageway 145. The cooling gas may be introduced into the cooling gas inlet 145b. A first gas outlet 145c may extend from the first gas passageway 145 to the lower surface of the second block 142. The SiH₄ gas may be injected through the first gas outlet 145c.

A second gas passageway 146 may be formed at an upper surface of the third block 143. Because the upper surface of the third block 143 may make contact with the lower surface of the second block 142, the second gas passageway 146 may be isolated from the outside. A second gas inlet 146a may be in fluid communication with the second gas passageway 146. The PH₃ gas may be introduced into the second gas inlet 146a. A second gas outlet 146b may extend to the lower surface of the third block 143. The PH₃ gas may be injected through the second gas outlet 146b. A first gas outlet line 145d may be vertically formed through the third block 143. The first gas outlet line 145d configured to inject the SiH₄ gas may be in fluid communication with the first gas outlet 145c. The first gas outlet line 145d may be arranged at a central portion of the third block 143. Therefore, the SiH₄ gas may be injected through the central portion of the third block 143. In contrast, the PH₃ gas may be injected through an edge portion of the third block 143.

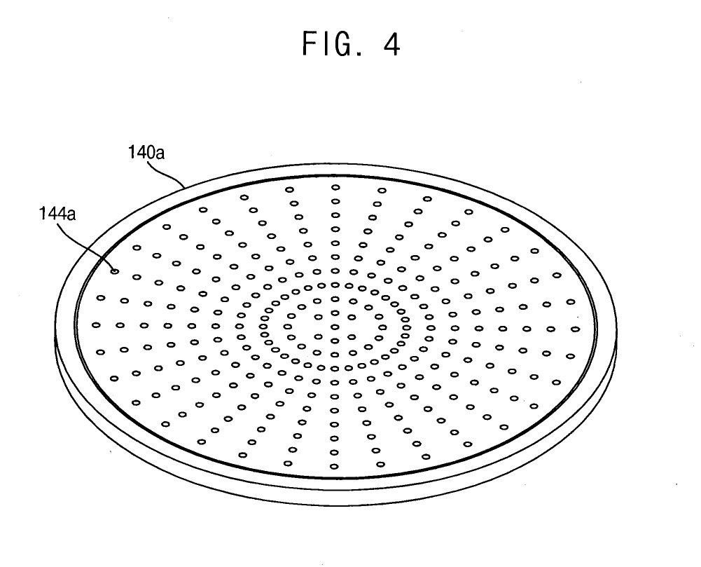

FIGS. 4 to 6 are a perspective view and plan views illustrating showerheads in accordance with example embodiments.

Referring to FIG. 4, a showerhead 140a of this example embodiment may have a plurality of circular holes 144a. The circular holes 144a may be concentrically arranged with respect to the center point of the showerhead 140a. The open ratio of the circular holes 144a may be about 30%.

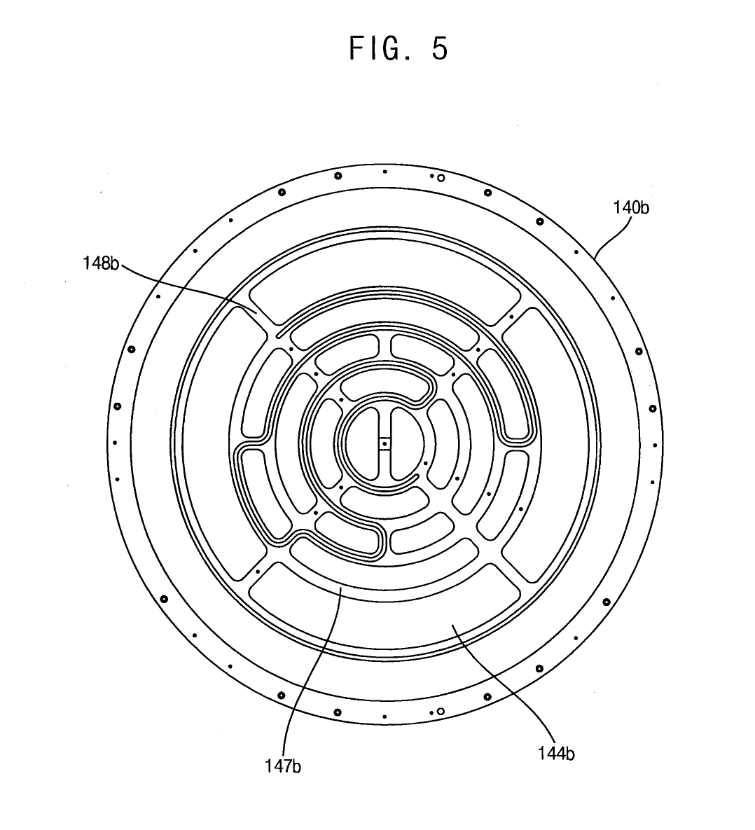

Referring to FIG. 5, a showerhead 140b of this example embodiment may have a plurality of circular portions 147b and two straight portions 148b. The circular portions 147b may be concentrically arranged with respect to the center point of the showerhead 140b. The straight portions 148b may cross or be aligned with the center point of the showerhead 140b. Further, the straight portions 148b may lie at right angles to each other. Thus, the showerhead 140b may have a plurality of openings 144b defined by the circular portions 147b and the straight portions 148b. The open ratio of the openings 144b may be about 60%.

Referring to FIG. 6, a showerhead 140c of this example embodiment may have a plurality of circular holes 144c. The circular holes 144c may include an edge hole arranged along a single circumferential line or path, and center holes arranged in a concentrated manner at a central portion of the showerhead 140c. The open ratio of the circular holes 144c may be about 60%.

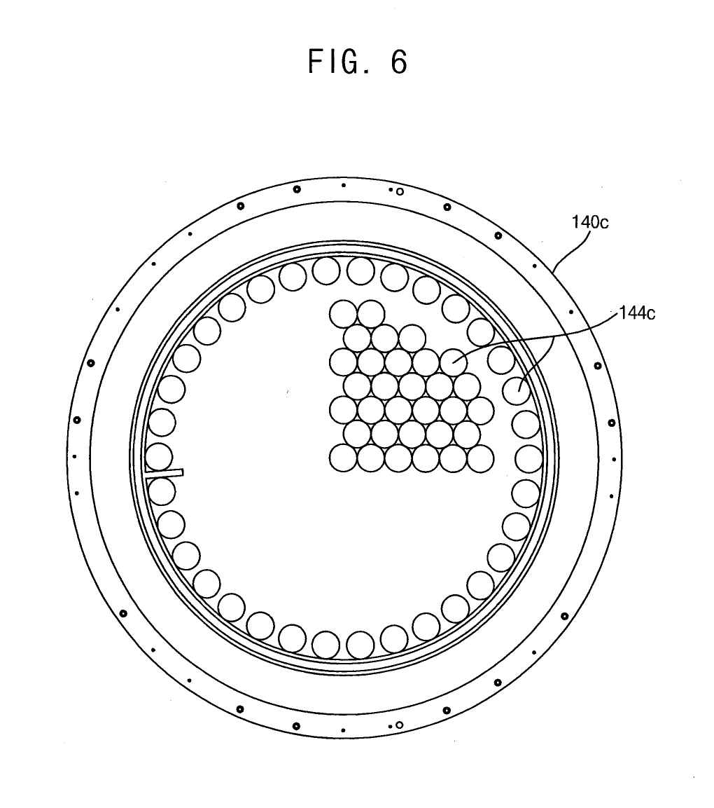

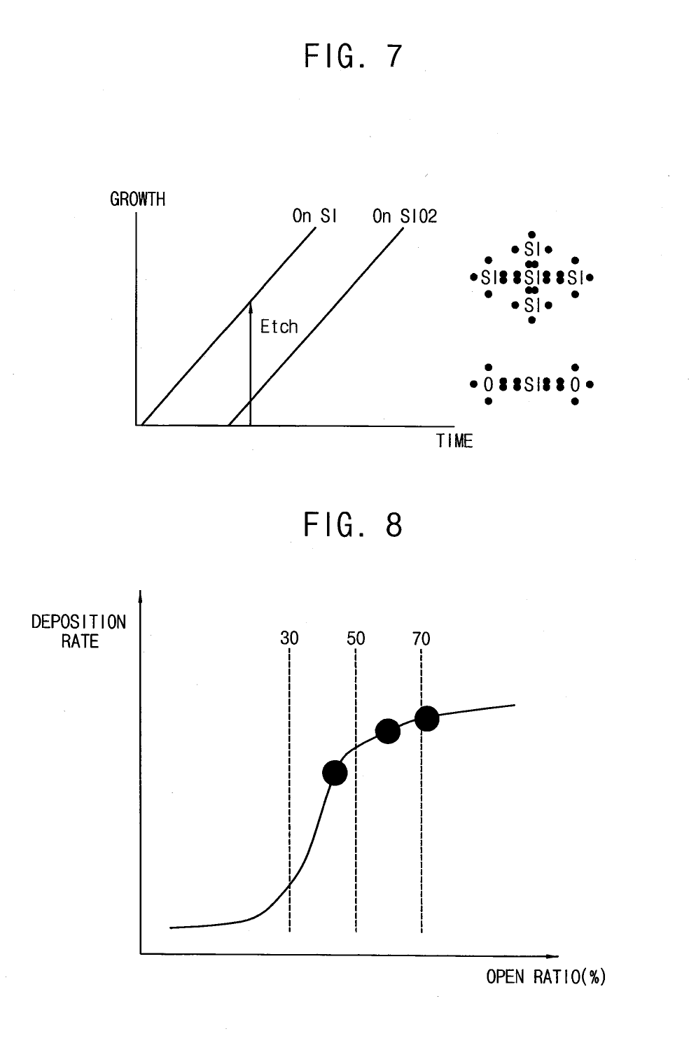

FIG. 7 is a graph showing a growth thickness of an epitaxial layer by lapse of time, and FIG. 8 is a graph showing a deposition rate of an epitaxial layer with respect to an open ratio of a showerhead.

Referring to FIG. 7, in order to form the epitaxial layer, it may be required to generate an SiH₄ plasma. Further, in order to selectively deposit the epitaxial layer, it may be required an incubation time in accordance with kinds or types of the substrate. Furthermore, the epitaxial layer may be formed on a silicon oxide layer as well as a silicon layer. Thus, it may be required to etch the epitaxial layer on the silicon oxide layer using a hydrogen plasma. The SiH₄ plasma and the hydrogen plasma may be dependent upon the open ratio of the showerhead 140. As a result, a deposition rate of the epitaxial layer may vary in accordance with the open ratio of the showerhead 140.

Referring to FIG. 8, it can be noted that the deposition rate of the epitaxial layer may be increased within the open ratio of the showerhead 140 of about 30% to about 70%. Particularly, it can be noted that the epitaxial layer may have the highest deposition rate within the open ratio of the showerhead 140 of about 45% to about 65%.

Referring again to FIG. 1, the first nozzle 150 may be arranged at an upper portion of the inner surface of the chamber 110. The first nozzle 150 may inject a first reaction gas to the first region R1. In example embodiments, the first reaction gas may include a gas including hydrogen. For example, the first reaction gas may include a hydrogen chloride (HCl) gas. The first reaction gas may have a first dissociation energy that may be higher than the second dissociation energy. Therefore, a second plasma may be generated from the second reaction gas by applying the second energy, which may be lower than the first energy for generating the first plasma from the first reaction gas, to the second reaction gas. Further, the first reaction gas may further include an argon gas. The argon gas may function to stabilize the first plasma generated in the first region R1.

The first reaction gas may be converted into the first plasma in the first region R1 by the plasma-generating unit 170. The first plasma may be introduced into the second region R2 through the openings 144 of the showerhead 140. Thus, the energy of the first plasma may be transferred to the second reaction gas. As a result, the generation of the second plasma may be assisted by the energy of the first plasma. Further, the first plasma may also function to diffuse the second plasma. Furthermore, the hydrogen in the first plasma may etch the insulating layer on the semiconductor substrate. Particularly, the argon in the first plasma may stabilize the first plasma.

As mentioned above, the showerhead 140 may divide the inner space of the chamber 110 into the first region R1 and the second region R2 that may be isolated from each other. Thus, the first reaction gas may not directly make contact with the second reaction gas. Therefore, the first plasma may be independently generated from the first reaction gas in the first region R1. The second plasma may also be independently generated from the second reaction gas in the second region R2. As a result, generation recipes of the first plasma and the second plasma may be independently and accurately controlled in accordance with kinds and types of the first reaction gas and the second reaction gas.

The plasma-generating unit 170 may generate the first plasma and the second plasma from the first reaction gas and the second reaction gas, respectively. In example embodiments, the plasma-generating unit 170 may apply microwaves to the first reaction gas and the second reaction gas to generate the first plasma and the second plasma.

The plasma-generating unit 170 may include a slot antenna 172, a microwave source 174, a matcher 176 and a coaxial waveguide 179. The slot antenna 172 may be arranged in or on the insulating block 180. The slot antenna 172 may transfer the microwave to the insulating block 180 to form an electric field on a lower surface of the insulating block 180. The microwave source 174 may supply the microwave to the slot antenna 172 through the matcher 176 and the coaxial waveguide 179.

In example embodiments, the microwave may be transferred to the second region R2 through the first region R1 from the slot antenna 172. For example, when the microwave applied to the first reaction gas in the first region R1 may correspond to the first microwave having the first energy, the first energy of the first microwave after generating the first plasma from the first reaction gas may be decreased. Here, the first energy may be no less than the dissociation energy of the first reaction gas (e.g., at least the dissociation energy of the first reaction gas). The second energy may be no less than the dissociation energy of the second reaction gas (e.g., at least the dissociation energy of the second reaction gas). Thus, the first microwave may be converted into the second microwave having the second energy lower than the first energy. The second microwave may be applied to the second reaction gas in the second region R2 through the openings 144 of the showerhead 140 to generate the second plasma from the second reaction gas. Further, the first plasma may also be introduced into the second region R2 through the openings 144 of the showerhead 140 so that the energy of the first plasma may be applied to the second reaction gas. As a result, because the energy of the first microwave as well as the energy of the second microwave may be applied to the second reaction gas, the second plasma generated from the second reaction gas may be stably maintained.

The second nozzle 160 may be arranged at a lower portion of the inner surface of the chamber 110. The second nozzle 160 may inject a blocking gas into the second region R2. The second nozzle 160 may inject the blocking gas from the inner surface of the chamber 110 toward an edge portion of the semiconductor substrate on the stage 120 to suppress deviations of the first plasma and the second plasma from the edge portion of the semiconductor substrate. That is, the blocking gas may serve as an air curtain configured to surround the edge portion of the semiconductor substrate. In example embodiments, the blocking gas may include an inert gas such as a hydrogen gas.

Additionally, the apparatus 100 may further include a vacuum pump configured to exhaust byproducts generated in the chamber 100.

In example embodiments, the apparatus 100 may be used for forming the layer on the substrate. Alternatively, the apparatus 100 may be used for cleaning, etching, etc., the substrate.

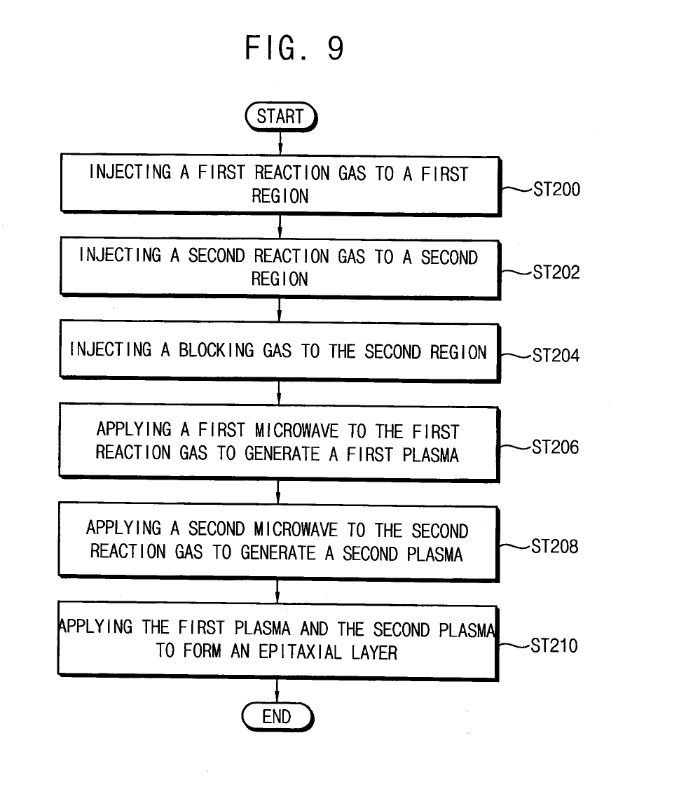

FIG. 9 is a flow chart illustrating a method of forming an epitaxial layer using the apparatus in FIG. 1.

Referring to FIGS. 1 and 9, in step ST200, the first nozzle 150 may inject the first reaction gas into the first region R1. In example embodiments, the first reaction gas may include the hydrogen gas and the argon gas.

In step ST202, the showerhead 140 may inject the second reaction gas into the second region R2. The second reaction gas may include the SiH₄ gas and the PH₃ gas.

In step ST204, the second nozzle 160 may inject the blocking gas into the second region R2. In example embodiments, the blocking gas may include an inert gas such as the hydrogen gas. Further, the step ST200, the step ST202 and the step ST204 may be performed simultaneously.

In step ST206, the slot antenna 172 may apply the first microwave having the first energy to the first reaction gas in the first region R1 to generate the first plasma from the first reaction gas. The first plasma may be introduced into the second region R2 through the openings 144 of the showerhead 140.

In step ST208, the slot antenna 172 may apply the second microwave having the second energy to the second reaction gas in the second region R2 to generate the second plasma from the second reaction gas.

In example embodiments, the first microwave after generating the first plasma from the first reaction gas may be converted into the second microwave having the second energy lower than the first energy. Further, the first plasma may be introduced into the second region R2 through the openings 144 of the showerhead 140 together with the second microwave so that the energy of the first plasma may also be applied to the second reaction gas. As a result, because the first energy of the first microwave and the second energy of the second microwave may be applied to the second reaction gas, the second plasma may be stably generated from the second reaction gas.

In step ST210, the first plasma and the second plasma may be applied to the semiconductor substrate to grow the epitaxial layer from the semiconductor substrate. During the growth process, the blocking gas injected from the second nozzle 160 may suppress the deviations of the first plasma and the second plasma from the edge portion of the semiconductor substrate.

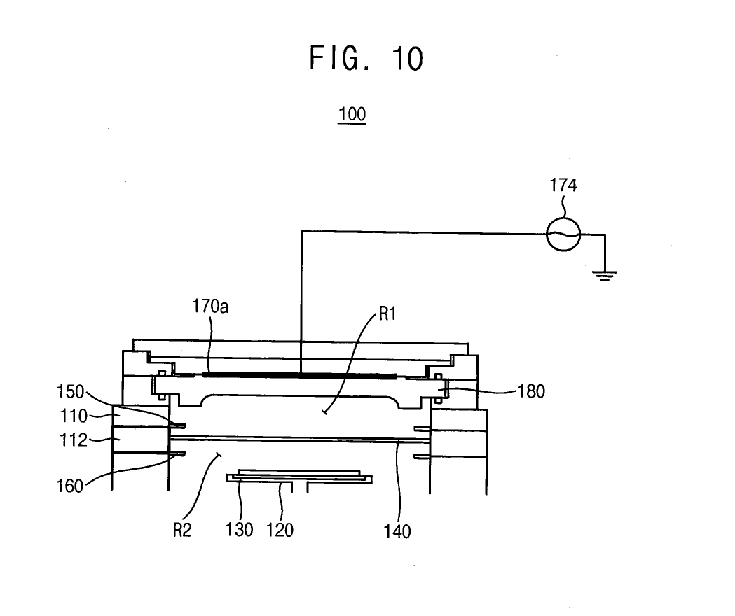

FIG. 10 is a cross-sectional view illustrating an apparatus for processing a substrate in accordance with example embodiments.

An apparatus 100a for processing a substrate in accordance with this example embodiment may include elements substantially the same as those of the apparatus 100 in FIG. 1 except for a plasma-generating unit. Thus, the same reference numerals may refer to the same elements and any further description with respect to the same elements may be omitted herein for brevity.

Referring to FIG. 10, a plasma-generating unit may include an electrode 170a. The electrode 170a may form an electric field in the first region R1 and the second region R2 to generate a first plasma and a second plasma from the first reaction gas and the second reaction gas, respectively.

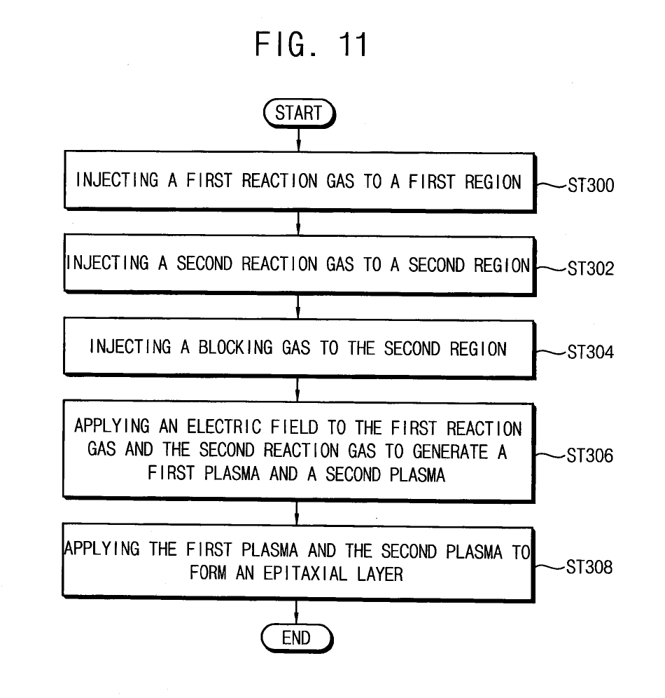

FIG. 11 is a flow chart illustrating a method of forming an epitaxial layer using the apparatus in FIG. 10.

Referring to FIGS. 10 and 11, in step ST300, the first nozzle 150 may inject the first reaction gas into the first region R1. In example embodiments, the first reaction gas may include the hydrogen gas and the argon gas.

In step ST302, the showerhead 140 may inject the second reaction gas into the second region R2. The second reaction gas may include the SiH₄ gas and the PH₃ gas.

In step ST304, the second nozzle 160 may inject the blocking gas into the second region R2. In example embodiments, the blocking gas may include an inert gas such as the hydrogen gas. Further, the step ST200, the step ST202 and the step ST204 may be performed simultaneously.

In step ST306, the electrode 170a may apply the electric field to the first reaction gas in the first region R1 and the second reaction gas in the second region R2 to generate the first plasma and second plasma from the first reaction gas and the second reaction gas, respectively.

In step ST308, the first plasma and the second plasma may be applied to the semiconductor substrate to grow the epitaxial layer from the semiconductor substrate. During the growth process, the blocking gas injected from the second nozzle 160 may suppress the deviations of the first plasma and the second plasma from the edge portion of the semiconductor substrate.

According to example embodiments, the epitaxial layer may be formed using the plasma. Thus, the epitaxial layer may be formed at a temperature relatively lower than a temperature in a heating process. Further, the first plasma and the second plasma may be generated in the first region and the second region that may be isolated from each other, so that the plasma may have a desired density. As a result, the epitaxial layer formed using the plasma may have a desired shape. Particularly, the blocking gas may be injected toward the edge of the substrate so that the epitaxial layer may have improved thickness uniformity.

Further, the apparatus may individually generate the first plasma and the second plasma in the first region and the second region that may be isolated from each other by the showerhead so that the generations of the first plasma and the second plasma may be accurately controlled. Particularly, the generation of the second plasma may be assisted by introducing the first plasma into the second reaction gas so that recipes for generating the second plasma may be optimized.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming an epitaxial layer on a substrate, the method comprising:
generating a first plasma from a first reaction gas in a first region of a chamber;
applying the first plasma to a second reaction gas in a second region of the chamber that is isolated from the first region to generate a second plasma from the second reaction gas;
injecting a blocking gas to an edge portion of the substrate in the second region to suppress horizontal diffusions of the first plasma and the second plasma; and
applying the first plasma and the second plasma to the substrate to form the epitaxial layer.

2. The method of claim 1, wherein generating the first plasma comprises applying a first microwave to the first reaction gas, and generating the second plasma comprises applying a second microwave having an energy lower than that of the first microwave to the second reaction gas.

3. The method of claim 1, wherein the second region is positioned between the substrate and the first region.

4. The method of claim 1, wherein the first reaction gas comprises a hydrogen gas and an argon gas.

5. The method of claim 1, wherein the second reaction gas comprises a silicon gas and a PH₃ gas.

6. The method of claim 1, wherein the blocking gas comprises a hydrogen gas.

7. An apparatus for processing a substrate, the apparatus comprising:
a chamber configured to receive the substrate;
a showerhead dividing an inner space of the chamber into a first region and a second region, the showerhead configured to inject a second reaction gas to the substrate through the second region;
a first nozzle configured to inject a first reaction gas into the first region;
a plasma-generating unit configured to generate a first plasma from the first reaction gas in the first region and a second plasma from the second reaction gas in the second region; and
a second nozzle arranged in the second region and configured to inject a blocking gas to an edge portion of the substrate for suppressing horizontal diffusions of the first plasma and the second plasma.

8. The apparatus of claim 7, wherein the first region is positioned between the showerhead and the plasma-generating unit, and the second region is positioned between the showerhead and the substrate.

9. The apparatus of claim 7, wherein the showerhead has a plurality of openings configured to inject the second reaction gas, and an open ratio of a total area of the openings with respect to a surface area of the showerhead is about 30% to about 70%.

10. The apparatus of claim 7, wherein the showerhead comprises:
a first block;
a second block contacting a lower surface of the first block, the second block having a first gas passageway into which a silicon gas in the second reaction gas is introduced; and
a third block contacting a lower surface of the second block, the third block having a second gas passageway into which a PH₃ gas in the second reaction gas is introduced.

11. The apparatus of claim 10, wherein the third block comprises:
a first gas outlet in fluid communication with the first gas passageway to inject the silicon gas; and
a second gas outlet in fluid communication with the second gas passageway to inject the PH₃ gas.

12. The apparatus of claim 11, wherein the first gas outlet is positioned at a central portion of the third block, and the second gas outlet is positioned at an edge portion of the third block.

13. The apparatus of claim 7, wherein the plasma-generating unit comprises a microwave-applying member configured to apply a microwave to the first and second reaction gases.

14. The apparatus of claim 7, further comprising a stage arranged on a bottom surface of the chamber to support the substrate.

15. The apparatus of claim 14, further comprising a heater arranged in the stage.

16. An apparatus for processing a substrate, the apparatus comprising:
a chamber;
a showerhead in the chamber, the showerhead dividing an inner space of the chamber into an upper region and a lower region;
a stage configured to support the substrate in the lower region;
a first nozzle configured to inject a first reaction gas into the upper region;
at least one gas outlet in the showerhead configured to inject a second reaction gas into the lower region; and
a plasma-generating unit configured to generate a first plasma from the first reaction gas in the upper region and a second plasma from the second reaction gas in the lower region.

17. The apparatus of claim 16, further comprising:
a first gas passageway in the showerhead through which a silicon gas in the second reaction gas is introduced to the showerhead; and
a second gas passageway in the showerhead through which a PH₃ gas in the second reaction gas is introduced to the showerhead.

18. The apparatus of claim 17, wherein the at least one gas outlet comprises:
a first gas outlet that is in fluid communication with the first gas passageway and is configured to inject the silicon gas into the lower region; and
a second gas outlet that is in fluid communication with the second gas passageway and is configured to inject the PH₃ gas into the lower region.

19. The apparatus of claim 18, wherein the first gas outlet is positioned at a central portion of the showerhead, and the second gas outlet is positioned at an edge portion of the showerhead.

20. The apparatus of claim 16, further comprising a second nozzle configured to inject a blocking gas into the lower region and to an edge portion of the substrate for suppressing horizontal diffusion of the first plasma and the second plasma.
